(19) United States
(12) Patent Application Publication
(10) Pub. No.: US 2005/0271216 A1
(43) Pub. Date: Dec. 8, 2005

(54) Method and apparatus for loudspeaker equalization

(76) Inventor: Khosrow Lashkari, Fremont, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/145,411

(22) Filed: Jun. 3, 2005

Related U.S. Application Data
(60) Provisional application No. 60/577,375, filed on Jun. 4, 2004.

(51) Int. Cl. H04R 29/00; H03G 3/00

(52) U.S. Cl. 381/59; 381/61

(57) ABSTRACT

A method, apparatus and system are disclosed herein for loudspeaker equalization. In one embodiment, the system comprises an input for receiving samples of an input signal, a pre-compensator to produce a pre-compensated output in response to the samples of an input signal, parameters of a loudspeaker model, and previously predistorted samples of the input signal, and a loudspeaker, corresponding to the loudspeaker model, to produce an audio output in response to the pre-compensated output.

### PRIORITY

The present patent application claims priority to the corresponding provisional patent application Ser. No. 60/577,375, titled, “Method And Apparatus For Loudspeaker Equalization Using Adaptive Feedback And Exact Inverse” filed on Jun. 4, 2004, which is incorporated by reference herein.

### FIELD OF THE INVENTION

The present invention relates to the field of audio loudspeakers; more particularly, the present invention relates to compensating for distortions produced by small loudspeakers.

### BACKGROUND OF THE INVENTION

Codec technology has advanced to the point that analog input and output (I/O) processing in mobile devices determine the limitations in audio and speech quality. Specifically, small loudspeakers with nonlinear characteristics are a major source of audio degradation in terminal devices such as, for example, cellular phones and personal digital assistants (PDAs).

Loudspeakers have two types of distortions: 1) linear distortions (low frequency suppression, resonances, etc.); and 2) non-linear distortions. The amplitudes and phases of the loudspeaker's frequency response characterize the linear distortion. The effect of linear distortion is to alter the amplitudes and phases of the signal's frequency content. Linear distortion does not add any extra frequencies to the sound and can be easily compensated using a linear filter with a frequency response that is the inverse of the loudspeaker's linear frequency response.

Non-linear distortion can lead to a more severe degradation of the sound. Extra frequency components known as harmonics and intermodulation distortions that may not be present in the original sound could appear. These “extra sounds” can alter the original sound in a way that it is perceived as harsh and unnatural. As is well known in the art, sound is produced by the vibration of a loudspeaker's diaphragm or horn. Generally, nonlinear distortions are higher for larger excursions of the loudspeaker's diaphragm, which occur at lower frequencies and also at resonant frequencies of the loudspeaker.

Exact compensation of non-linear distortions requires a predistortion filter that is the exact inverse of the loudspeaker model.

Volterra expansions have been used in the art to model the linear (H1) and nonlinear (H2, H3, . . . ) components of a loudspeaker's response as shown in FIG. 1. These components are estimated from the loudspeaker's input and output measurements. Applying sinusoidal signals and measuring the extent to which harmonics or combination tones are generated at the output of the nonlinear system have traditionally been used to measure nonlinear distortion. For example, see M. Tsujikawa, T. Shiozaki, Y. Kajikawa, Y. Nomura, “Identification and Elimination of Second-Order Nonlinear Distortion of Loudspeaker Systems using Volterra Filter,” ISCAS 2000-IEEE International Symposium on Circuits and Systems, pp. V-249-252, May 2000. In contrast to the sinusoidal input approach, a random noise is often used to analyze loudspeaker characteristics. For example, see V. J. Matthews, “Adaptive Polynomial Filters,” IEEE SP magazine, vol. 8, no. 3, pp. 10-26, July 1991. The random input approach approximates a frequency-multiplexed input such as music and does not require repeating the same experiments by changing the frequency of the input tones. The random input approach usually involves modeling a nonlinear system with a Volterra series representation. A least-squares technique such as the least mean squares (LMS) or recursive least squares (RLS) is then used to compute the parameters of the linear (H1) and the nonlinear (H2, H3, . . . ) components.

In general, the input-output relationship of the loudspeaker in time-domain is given by a p-th order Volterra expansion as:

$$y ( n ) = {\sum }_{k = 0}^{p} {H}_{k} [ x ( n ) ]$$

where, Hₖ=hₖ (m₁, m₂, m₃, . . . mₖ) is the k-th order Volterra kernel and Hₖ [x(n)] is given as:

$${H}_{k} [ x ( n ) ] = {\sum }_{{m}_{1} = 0}^{{M}_{k}} {\sum }_{{m}_{2} = 0}^{{M}_{k}} {\sum }_{{m}_{3} = 0}^{{M}_{k}} ⋯ {\sum }_{{m}_{k} = 0}^{{M}_{k}} {h}_{k} ( {m}_{1} , {m}_{2} , {m}_{3} , … {m}_{k} ) x ( n - {m}_{1} ) x ( n - {m}_{2} ) x ( n - {m}_{3} ) … x ( n - {m}_{k} )$$

It is generally assumed that loudspeakers can be sufficiently modeled by a second or third order Volterra model. The second order model is a special case of (1) and is given as:

$$y ( n ) = {h}_{0} + {\sum }_{i = 0}^{{M}_{1}} {h}_{1} ( i ) x ( n - i ) + {\sum }_{{m}_{1} = 0}^{{M}_{2}} {\sum }_{{m}_{2} = 0}^{{M}_{2}} {h}_{2} ( {m}_{1} , {m}_{2} ) x ( n - {m}_{1} ) x ( n - {m}_{2} )$$

The first term is a constant and is generally assumed to be zero, the second term is the linear response (H1), and the third term is the quadratic nonlinear response (H2).

To compensate for the linear and nonlinear distortions in the electro-acoustic conversion, a predistortion filter is used. FIG. 2 illustrates an audio system having an input signal (d (n)) from a signal source 201 that is passed through a predistortion filter 202 between audio signal source 201 and loudspeaker 203. Predistortion filter 202 is sometimes referred to as a precompensator, a linearizer or an equalizer. The moving coil of loudspeaker 203 is driven by a prefiltered signal dₚᵣₑ(n) that is output from predistortion filter 202. The loudspeaker model is used to find a non-linear predistortion filter 202 to be placed between audio signal source 201 and loudspeaker 203. The filtering performed by predistortion filter 202 is designed to be opposite to the distortion of loudspeaker 203, so that the actual displacement of the moving coil accurately matches the ideal motion prescribed by the original signal d(n). That is, ideally, predistortion filter 202 should produce a predistorted signal dₚᵣₑ(n) so that when fed to loudspeaker 203, the output acoustic signal is an exact replica of the original audio signal. In this case, both the linear and the nonlinear distortions are completely compensated.

Finding the exact inverse is not straightforward and poses a challenge in equalizing any nonlinear system including nonlinear loudspeakers. A number of approximate solutions have been used. For example, see W. Frank, R. Reger, and U. Appel, “Loudspeaker Nonlinearities-Analysis and Compensation”, Conf. Record 26th, Asilomar Conference on Signals, Systems and Computers, Pacific Grove, Calif., pp. 756-760, Oct. 1992; X. Y. Gao, W. M. Snelgrove, “Adaptive Linearization of a Loudspeaker,” Proc. IEEE Intl. Conf. Acoust., Speech, Signal Processing, pp. 3589-3592, 1991 and U.S. Pat. No. 6,408,079, entitled “Distortion Removal Apparatus, Method for Determining Coefficient for the Same, and Processing Speaker System, Multi-Processor, and Amplifier Including the Same,” issued Jun. 18, 2002. These schemes use the Volterra model of the loudspeaker to find a predistortion filter that is an approximation to the loudspeaker's nonlinear inverse. Typically, the approximate inverse has only a linear component and a quadratic component as shown in FIG. 3 where G₁ and G₂ are the linear and quadratic parts of the Volterra inverse.

The linear part is typically selected to completely compensate for the loudspeaker's linear distortion (G₁=H₁⁻¹) as described above. The second order or quadratic component of the predistortion filter is selected to completely compensate for the quadratic distortion of the loudspeaker (G₂=H₁⁻¹ H₂H₁⁻¹).

As a by-product of this compensation scheme, extraneous third and fourth order nonlinearities are introduced. Some prior art references describe using higher order (the so-called p-th order) predistortion filters to construct a better approximation to the nonlinear inverse. In such cases, higher order nonlinearities will be introduced at the loudspeaker output.

The p-th order Volterra inverse converges to the real inverse only if certain conditions are met. For small signal levels, Volterra preinverse improves the perceived sound quality from loudspeakers. It is stated in W. Frank, R. Reger, and U. Appel, “Loudspeaker Nonlinearities-Analysis and Compensation”, Conf. Record 26th , Asilomar Conference on Signals, Systems and Computers, Pacific Grove, Calif., pp. 756-760, Oct. 1992, that at nominal input power of the loudspeaker, the higher order distortions are small. While this might be true in applications where the loudspeaker is very close to the ear (such as in voice telephony), in future multimedia applications such as video phones and hand-free telephony, the loudspeaker is far from the listener's ear. These applications require higher playback levels.

For high playback levels, the p-th order Volterra inverse may not converge to the exact nonlinear inverse and, as a result, the extra distortions introduced by the predistortion filter maybe worse than the original uncompensated loudspeaker distortions. The structure of the p-th order Volterra inverse is such that linear distortions may be compensated at a high cost for nonlinear distortions. For large input levels, the third, fourth and higher order distortions become larger than the uncompensated distortions, thereby rendering the precompensation scheme useless. As a result, the sound quality of the Volterra precompensated loudspeaker may be lower than the uncompensated case.

### SUMMARY OF THE INVENTION

A method, apparatus and system are disclosed herein for loudspeaker equalization. In one embodiment, the system comprises an input for receiving samples of an input signal, a pre-compensator to produce a pre-compensated output in response to the samples of an input signal, parameters of a loudspeaker model, and previously predistorted samples of the input signal, and a loudspeaker, corresponding to the loudspeaker model, to produce an audio output in response to the pre-compensated output.

### BRIEF DESCRIPTION OF THE DRAWINGS

The present invention will be understood more fully from the detailed description given below and from the accompanying drawings of various embodiments of the invention, which, however, should not be taken to limit the invention to the specific embodiments, but are for explanation and understanding only.

FIG. 1 is a diagram illustrating a 2nd order loudspeaker model.

FIG. 2 is a block diagram of an audio system having a predistortion filter for loudspeaker equalization.

FIG. 3 is a diagram of one embodiment of the 2nd order predistortion filter.

FIG. 4 shows one embodiment using concepts and notations of adaptive filtering theory.

FIG. 5 shows an embodiment where the signal source is an analog source.

FIG. 6 shows an alternate embodiment where the sound level of the loudspeaker is controlled by a digital gain before the precompensator.

FIG. 7 shows an alternate embodiment wherein the sound level from the loudspeaker is controlled by the variable analog gain of a power amplifier before the loudspeaker.

FIG. 8 shows one embodiment of the precompensator consisting of five components.

FIG. 9 shows one embodiment of the exact inverse consisting of a polynomial coefficient calculator and a polynomial root solver.

FIG. 10 shows an alternate embodiment of the exact inverse where the polynomial presenting the exact inverse is a second-degree polynomial having three generally time-dependent coefficients.

FIG. 11 shows the flow diagram of one embodiment of a precompensation process performed by a precompensator.

FIG. 12 is a block diagram of an exemplary cellular phone.

FIG. 13 is a block diagram of an exemplary computer system.

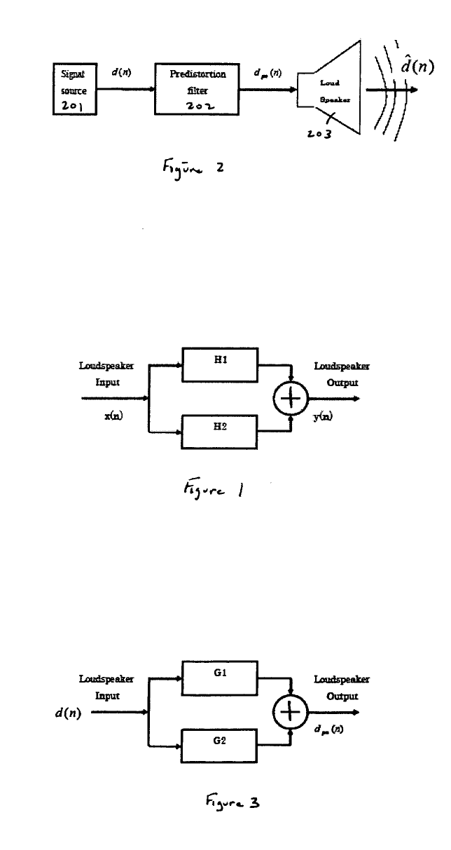

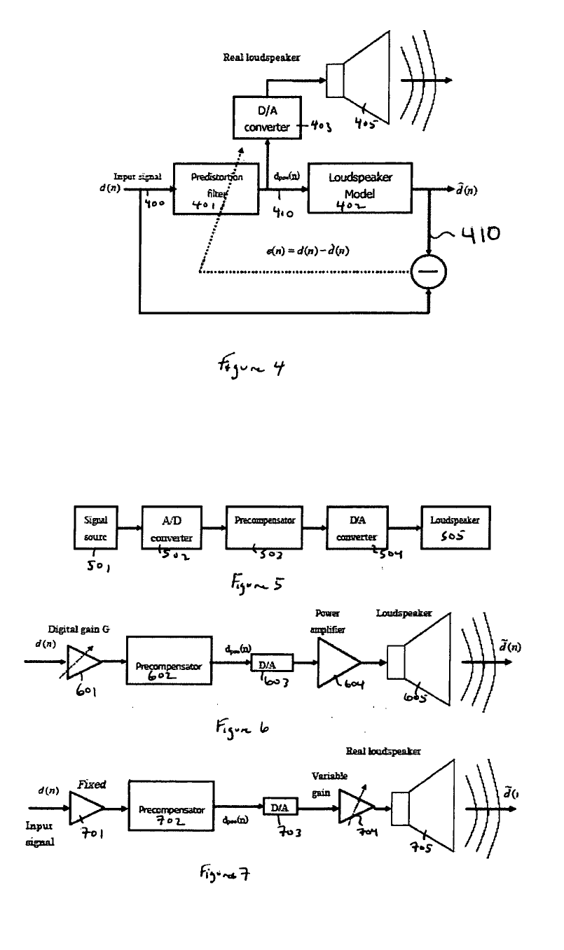

### DETAILED DESCRIPTION OF THE PRESENT INVENTION

A method and an apparatus for compensating loudspeaker's linear and nonlinear distortions using a nonlinear inverse and a feedback loop are described. In one embodiment, the inverse is an exact non-linear inverse. To compensate for the distortions of the electro-acoustic conversion in small loudspeakers, the signal is passed through the predistortion filter placed between the audio signal source and the loudspeaker.

Embodiments set forth herein compensate for a loudspeaker's linear and non-linear distortions using an exact nonlinear inverse and a feedback loop for adaptively adjusting the parameters of the predistortion filter so that the difference between the input and the precompensated output of the loudspeaker is minimized or substantially reduced. In one embodiment, the predistortion filter transforms the input signal using an inverse (e.g., an exact inverse) of the estimated loudspeaker transfer function and generates a reproduction of the input sound. In one embodiment, a feedback signal may be used to compute the exact inverse of a nonlinear system. The feedback is used to adaptively adjust the parameters of the predistortion filter so that the difference between the input and the precompensated output of the loudspeaker is reduced, and potentially minimized. The resulting improvement in quality makes the techniques described herein suitable for inclusion in applications where high quality sound at high playback levels is desired. Such applications include, but are not limited to, cellular phones, teleconferencing, videophones, videoconferencing, personal digital assistants, Wi-Fi, systems, etc.

In one embodiment, a model of the electroacoustic characteristics of the loudspeaker is used to derive a transfer function of the loudspeaker. The precompensator then performs an inverse of this transfer function. Accordingly, the output of the loudspeaker more closely resembles the original input signal.

In the following description, numerous details are set forth to provide a more thorough explanation of the present invention. It will be apparent, however, to one skilled in the art, that the present invention may be practiced without these specific details. In other instances, well-known structures and devices are shown in block diagram form, rather than in detail, in order to avoid obscuring the present invention.

Some portions of the detailed descriptions which follow are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The present invention also relates to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, and each coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description below. In addition, the present invention is not described with reference to any particular programming language. It will be appreciated that a variety of programming languages may be used to implement the teachings of the invention as described herein.

A machine-readable medium includes any mechanism for storing or transmitting information in a form readable by a machine (e.g., a computer). For example, a machine-readable medium includes read only memory (“ROM”); random access memory (“RAM”); magnetic disk storage media; optical storage media; flash memory devices; electrical, optical, acoustical or other form of propagated signals (e.g., carrier waves, infrared signals, digital signals, etc.); etc.

Overview

A method and apparatus for precompensation of linear and non-linear distortions of a loudspeaker in order to reduce loudspeaker distortions are described. In one embodiment, the method comprises performing adaptive precompensation by modifying the operation of a predistortion filter in response to the previous predistorted values and the original input signal, determining a precompensation error between the original input samples and the loudspeaker output and substantially reducing the precompensation error by computing the exact inverse of a loudspeaker's model. The difference between the input and the predicted loudspeaker output provides a feedback signal that is used to adjust the parameters of the precompensator so that the error is minimized or substantially reduced.

In one embodiment, substantial reduction in the precompensation error is achieved by computing the coefficients of a polynomial representing an inverse (e.g., an exact inverse), computing the predistorted signal by finding a real root of this polynomial, scaling and storing the root for the next coefficient computation, and rescaling the predistorted signal before sending it to the loudspeaker.

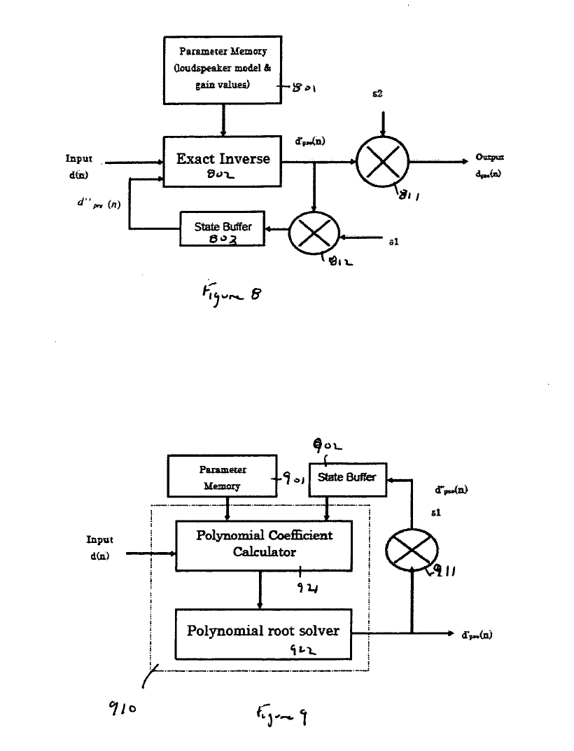

FIG. 4 is a general block diagram illustrating a predistortion filter with feedback for loudspeaker linearization. Referring to FIG. 4, input signal d(n) is fed into a time-varying predistortion filter 401. Predistortion filter 401 performs pre-compensation on the input signal d(n) prior to the input signal d(n) being sent to loudspeaker 405. The output of predistortion filter 401 is routed into a mathematical model of loudspeaker 405, referred to as loudspeaker model 402, and also to an analog-to-digital converter 403 that drives loudspeaker 405. The mathematical model 402 of loudspeaker 405 predicts the next output 410 of the loudspeaker \hat{d} (n). This predicted output 410 is used to derive a precompensation error signal (e(n)=d(n)−\hat{d} (n)) that is the difference between the ideal output and the predicted output of loudspeaker 405. Thus, predistortion filter 401 and loudspeaker model 402 operate as a precompensator with parameters that are adjusted in such a way that the precompensation error e(n) is minimized or substantially reduced.

In one embodiment, the mathematical model of the loudspeaker in general could be the p-th order Volterra model as described herein. For the purpose of illustrations, the exact inverse based on the second order Volterra model is described, but the method and apparatus described herein are not so limited and may also be used for models of higher order.

FIG. 5 is block diagram of another audio system in which the signal source is an analog source. Referring to FIG. 5, analog signal 501 is converted to a digital signal using an analog-to-digital (A/D) converter 502. The digital output of the A/D converter 502 feeds digital precompensator 503. Precompensator 503 produces a predistorted signal that when passed through loudspeaker 505 compensates for the linear and non-linear distortions. The digital output of precompensator 503 is fed into a digital-to-analog (D/A) converter 504. The analog output of D/A converter 504 drives loudspeaker 505.

FIG. 6 is a block diagram of an alternate embodiment of an audio system in which the sound level of the loudspeaker is controlled by a digital gain module prior to precompensation by the precompensator. Referring to FIG. 6, a variable digital gain module 601 receives a digital input signal. Variable digital gain module 601 controls the signal level of the digital input signal that is input into digital precompensator 602. Digital precompensator 602 performs precompensation as discussed above. The output of precompensator 602 is fed into a digital-to-analog (D/A) converter 603. Power amplifier 604 receives the analog signal output from D/A converter 603 and applies a fixed gain to the signal that drives loudspeaker 605.

FIG. 7 is a block diagram of an alternate embodiment of an audio system in which the sound level from the loudspeaker is controlled by the variable analog gain of a power amplifier before the loudspeaker. Referring to FIG. 7, a fixed gain module 701 adjusts the level of the input signal d(n). Precompensator 702 receives the output of fixed gain module 701. Precompensator 702 performs precompensation as discussed above. The output of the precompensator 702, referred to as dₚᵣₑ(n) is fed into a digital-to-analog (D/A) converter 703, which converts it from digital to analog. The analog signal from D/A converter 703 is input into a variable gain power amplifier 704 that drives loudspeaker 705. Variable gain amplifier 704 controls the sound level of loudspeaker 705.

FIG. 8 is a block diagram of one embodiment of the precompensator. Referring to FIG. 8, memory module 801 stores the parameters of the loudspeaker model and also various system parameters such as scale factors s1 and s2. In one embodiment, these parameters represent a second-order Volterra model. Parameters of the linear and nonlinear parts H1=[h₁(0), h₁(1), . . . h₁. (M₁)] and H2={h₂(ij), i,j=0,1, . . . M₂} are stored in memory 801. For higher-order Volterra models, the parameters of the higher order kernels are also stored. The digital signal d(n) is input into exact inverse module 802. The function of inverse module 802 is to perform an inverse non-linear operation. Inverse module 802 takes the input signal d(n) and scaled past values of its output {d′ₚᵣₑ(n-1), d′ₚᵣₑ(n-2, . . . } from a state buffer 802 and produces the current value of the output d′ₚᵣₑ(n). Past values of the predistorted signal are first scaled by multiplier 812 by a factor s1 using a gain module and stored in state buffer 802 as shown in FIG. 8.

The final output of the precompensator is a scaled version of the output from exact inverse module 802. This scaling is performed by a gain module 811 that has a gain of s2. In one embodiment, gains s1 and s2 are stored in parameter memory 801. Gains s1 and s2 could be fixed or variable depending on the embodiment. Alternative embodiments may use unity gain for s1 (s1=1) and store a related set of parameters, such as, for example, a properly scaled version of the model parameters in parameter memory 801.

FIG. 9 is a block diagram of one embodiment of the precompensator. Referring to FIG. 9, the precompensator comprises a polynomial coefficient calculator 921 and a polynomial root solver 922. Polynomial coefficient calculator module 921 computes the (p+1) coefficients of a p-th order polynomial using loudspeaker model parameters from parameter memory 901, the past values of the predistorted signal from state buffer 902 and the input signal d(n). A polynomial root solver 922 uses the computed coefficients and computes a real root of this polynomial. In one embodiment, the computed root constitutes the output d′ₚᵣₑ(n) of the exact inverse.

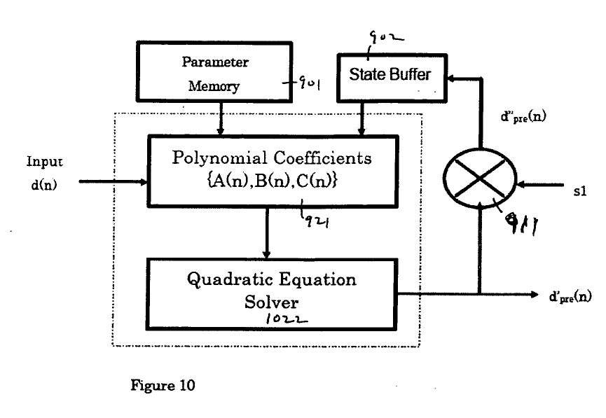

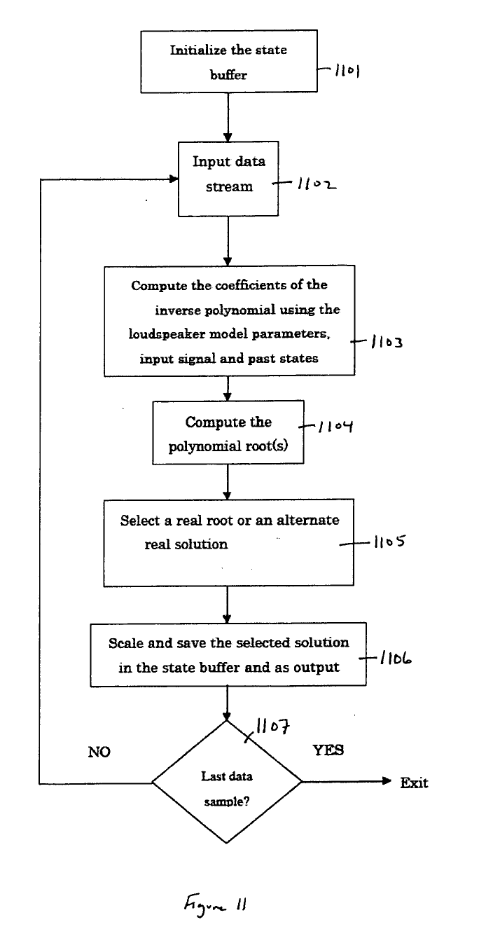

FIG. 10 is a block diagram of an alternative embodiment of the precompensator in which the polynomial representing the exact inverse is a second-degree polynomial having three generally time-dependent coefficients A(n), B(n), and C(n). In one embodiment, the quadratic equation in this case is given as:
A(n)d′²ₚᵣₑ(n)+B(n)d′ₚᵣₑ(n)+C(n)=0 (1)

Roots of this equation give the output of the exact inverse d′ₚᵣₑ(n). The polynomial root solver in this embodiment is a quadratic equation solver 1022.

One embodiment of a method to compute these coefficients are given by the following equations:

$$\begin{matrix}A ( n ) = {h}_{2} ( 0 , 0 ) & ( 2 a ) \\ B ( n ) = {h}_{1} ( 0 ) + {\sum }_{j = 1}^{{M}_{2}} {h}_{2} ( 0 , j ) {d}_{pre}^{″} ( n - j ) & ( 2 b ) \\ C ( n ) = - d ( n ) + {\sum }_{k = 1}^{{M}_{1}} {h}_{1} ( k ) {d}_{pre}^{″} ( n - k ) + {\sum }_{i = 1}^{{M}_{2}} {\sum }_{j = 1}^{{M}_{2}} {h}_{2} ( i , j ) {d}_{pre}^{″} ( n - i ) {d}_{pre}^{″} ( n - j ) & ( 2 c )\end{matrix}$$

As shown above, in one embodiment, the coefficients depend on the parameters of the loudspeaker model {H1, H2}, the past scaled values of the predistortion signal d″ₚᵣₑ(n) (the states) and the input signal d(n).

As is evident from equations (2a), (2b) and (2c), the coefficients of the quadratic equation are not constant; they depend on the past scaled values of the predistorted signal d″ₚᵣₑ(n-i) as well as the parameters of the loudspeaker model.

As illustrated by these equations, the feedback in FIG. 10 adjusts the parameters of the exact predistortion filter on a sample-by-sample basis. Thus, for each sample of the input signal, a different quadratic equation is solved. Therefore, the exact inverse is not fixed; its parameters change with time.

The roots in this embodiment are given by the following equation:

$${d}_{pre}^{′} ( n ) = \frac{- B ( n ) \pm \sqrt{{B}^{2} ( n ) - 4 A ( n ) C ( n )}}{2 A ( n )} \qquad ( 3 )$$

As shown herein, in general there is multiple roots. For a p-th order polynomial equation, there are in general p roots and for a quadratic equation there are in general two roots. All of these roots are possible candidates for solution. However, only one root is selected for subsequent processing. Various criteria can be employed to select a candidate solution. In one embodiment, the selected root is real. In case, no real root exists, an alternate real value for d′ₚᵣₑ(n) is selected so that the precompensation error e(n) is reduced, and potentially minimized. For a p-th order polynomial, if p is odd, at least one real root is guaranteed to exist. If p is even and no real root exists, a (p-1)-th order polynomial can be derived from the p-th order polynomial by differentiating relative to d′ₚᵣₑ(n). The derived polynomial has order (p-1), which will be odd and is guaranteed to have a real root. The real root of the (p-1)-th order polynomial reduces the precompensation error. For the case of a quadratic polynomial, if a real root does not exist, the alternate real solution that reduces the precompensation error is given by:

$${d}_{pre}^{′} ( n ) = \frac{- B ( n )}{2 A ( n )} \qquad ( 4 )$$

Different valid solutions (roots) may result in different overall performance for the precompensator. For example, some roots may produce a predistorted signal that has a bias value. Such properties may or may not be desirable for certain applications. Hence, a number of embodiments are possible depending on the method of selecting a root from a plurality of roots. In one embodiment, the real root with the smallest absolute value is used.

FIG. 11 is a flow diagram of one embodiment of a process for precompensating a signal. The process is performed by processing logic that may comprise hardware (e.g., circuitry, dedicated logic, etc.), software (such as is run on a general purpose computer system or a dedicated machine), or a combination of both. In one embodiment, the processing logic is part of the precompensator.

Referring to FIG. 11, the precompensation begins by processing logic initializing a state buffer (processing block 1101). With the state buffer initialized, processing logic receives an input date stream (processing block 1102). Processing logic computes the coefficients of the inverse polynomial using loudspeaker model parameters, past states of the predistortion filter (e.g., past predistored samples of the precompensator) and the input signal (processing block 1103). In one embodiment, the inverse polynomial is an exact inverse polynomial calculated according to equations (2a), (2b) and (2c).

After computing the coefficients, processing logic determines the roots of the inverse polynomial (processing block 1104) and selects a real root of the polynomial to reduce, and potentially minimize, the precompensation error (processing block 1105). In an alternative embodiment, processing logic selects an alternate real solution that reduces the precompensation error, such as described above.

After selection, processing logic scales and stores the selection (processing block 1106). In one embodiment, the scaled selection is stored in the state buffer for the next root computation. In one embodiment, the output of the root solver is scaled by another factor and output as the precompensator output.

Next, processing logic determines if this sample is the last (processing block 1107). If the input data is not exhausted, processing transitions to processing block 1102 where the next data sample is read and the computation of the polynomial coefficients, the roots and storage of the past states are repeated; otherwise, the process ends.

Components and Interface

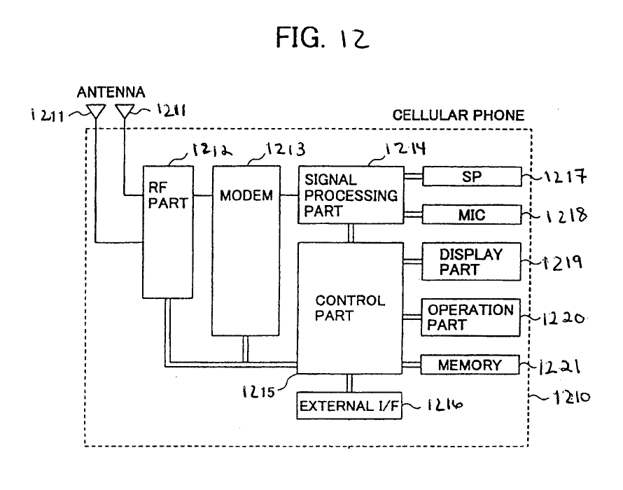

A number of components are included in devices and/or systems that include the techniques described herein. For example, a central processing unit (CPU) or a digital signal processor (DSP) for computing the coefficients and roots of the inverse polynomial. A memory for storing the loudspeaker model, the precompensator parameters and portions of the input signal is part of such a device and/or system. Furthermore, analog and digital gain elements may be included in the audio system. These may include digital multipliers and analog amplifiers. One such device is a cellular phone. FIG. 12 is a block diagram of one embodiment of a cellular phone.

Referring to FIG. 12, the cellular phone 1210 includes an antenna 1211, a radio-frequency transceiver (an RF unit) 1212, a modem 1213, a signal processing unit 1214, a control unit 1215, an external interface unit (external I/F) 1216, a speaker (SP) 1217, a microphone (MIC) 1218, a display unit 1219, an operation unit 1220 and a memory 1221.

The external terminal 1230 includes an external interface (external I/F) 1231, a CPU (Central Processing Unit) 1232, a display unit 1233, a keyboard 1234, a memory 1235, a hard disk 1236 and a CD-ROM drive 1237.

CPU 1232 in cooperation with the memories of cellular phone 1210 (e.g., memory 1221, the memory 1235, and hard disk 1236) cooperate to perform the operations described above.

An Exemplary Computer System

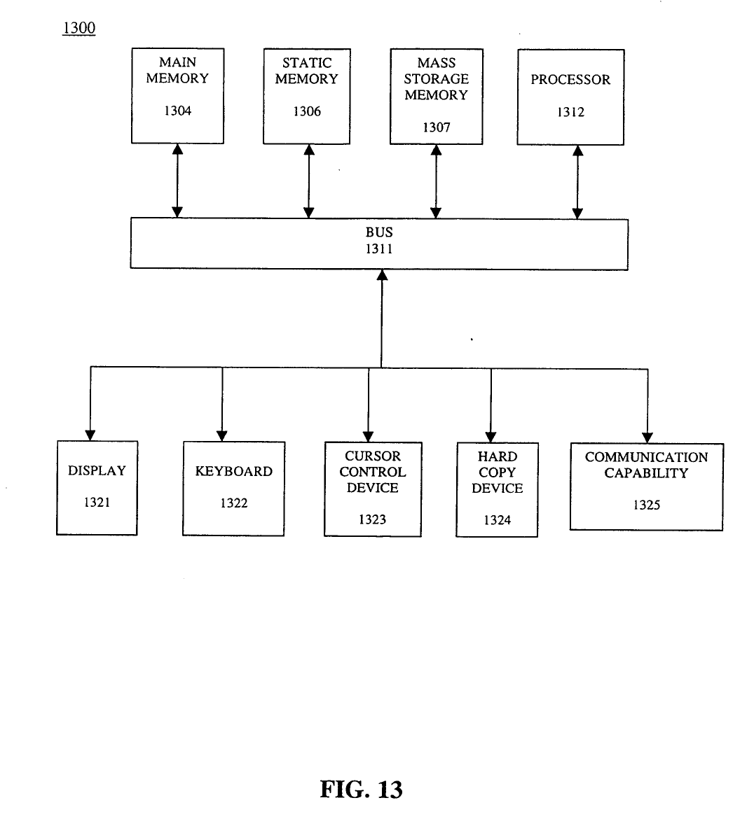

FIG. 13 is a block diagram of an exemplary computer system that may perform one or more of the operations described herein. Note that these blocks or a subset of these blocks may be integrated into a device such as, for example, a cell phone, to perform the techniques described herein.

Referring to FIG. 13, computer system 1300 may comprise an exemplary client or server computer system. Computer system 1300 comprises a communication mechanism or bus 1311 for communicating information, and a processor 1312 coupled with bus 1311 for processing information. Processor 1312 includes a microprocessor, but is not limited to a microprocessor, such as, for example, Pentium™, PowerPC™, Alpha™, etc.

System 1300 further comprises a random access memory (RAM), or other dynamic storage device 1304 (referred to as main memory) coupled to bus 1311 for storing information and instructions to be executed by processor 1312. Main memory 1304 also may be used for storing temporary variables or other intermediate information during execution of instructions by processor 1312.

Computer system 1300 also comprises a read only memory (ROM) and/or other static storage device 1306 coupled to bus 1311 for storing static information and instructions for processor 1312, and a data storage device 1307, such as a magnetic disk or optical disk and its corresponding disk drive. Data storage device 1307 is coupled to bus 1311 for storing information and instructions.

Computer system 1300 may further be coupled to a display device 1321, such as a cathode ray tube (CRT) or liquid crystal display (LCD), coupled to bus 1311 for displaying information to a computer user. An alphanumeric input device 1322, including alphanumeric and other keys, may also be coupled to bus 1311 for communicating information and command selections to processor 1312. An additional user input device is cursor control 1323, such as a mouse, trackball, trackpad, stylus, or cursor direction keys, coupled to bus 1311 for communicating direction information and command selections to processor 1312, and for controlling cursor movement on display 1321.

Another device that may be coupled to bus 1311 is hard copy device 1324, which may be used for printing instructions, data, or other information on a medium such as paper, film, or similar types of media. Furthermore, a sound recording and playback device, such as a speaker and/or microphone may optionally be coupled to bus 1311 for audio interfacing with computer system 1300. Another device that may be coupled to bus 1311 is a wired/wireless communication capability 1325 to communication to a phone or handheld palm device.

Note that any or all of the components of system 1300 and associated hardware may be used in the present invention. However, it can be appreciated that other configurations of the computer system may include some or all of the devices.

Thus, as described above, at least one embodiment provides better compensation for loudspeaker distortions resulting in higher quality sound from the loudspeaker.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims which in themselves recite only those features regarded as essential to the invention.

1. An audio system comprising:
an input for receiving samples of an input signal;
a pre-compensator to produce a pre-compensated output in response to the samples of an input signal, parameters of a loudspeaker model, and previously predistorted samples of the input signal;
a loudspeaker, corresponding to the loudspeaker model, to produce an audio output in response to the pre-compensated output.

2. The audio system defined in claim 1 wherein the pre-compensator uses non-linear compensation to modify the samples of the input signal in a manner opposite to distortion that is to occur from the loudspeaker.

3. The audio system defined in claim 1 wherein the pre-compensator comprises an inverse module to compute the inverse of the loudspeaker model.

4. The audio system defined in claim 3 wherein the inverse module computes the inverse of the loudspeaker model using the samples of an input signal, parameters of a loudspeaker model, and previously distorted samples of the input signal.

5. The audio system defined in claim 3 wherein the inverse module comprises:
a polynomial coefficient calculator to compute coefficients of a polynomial; and
a polynomial root solver to generate a root of the polynomial in response to the coefficients.

6. The audio system defined in claim 5 wherein the polynomial coefficient calculator computes the coefficients using the samples of an input signal, parameters of the loudspeaker model, and previously predistorted samples of the input signal.

7. The audio system defined in claim 5 wherein the inverse is given by a second order polynomial.

8. The audio system defined in claim 5 wherein the root is a real root.

9. The audio system defined in claim 5 wherein the polynomial root solver comprises a quadratic equation solver.

10. The audio system defined in claim 5 wherein the polynomial root solver computes roots of the polynomial and selects a real root from the roots.

11. The audio system defined in claim 5 further comprising a digital multiplier to scale output of the inverse module.

12. The audio system defined in claim 11 further comprising a gain unit to scale output of the inverse module to drive the loudspeaker.

13. The audio system defined in claim 3 further comprising a memory to store the parameters of the loudspeaker model.

14. The audio system defined in claim 3 further comprising a buffer memory to store the states of the inverse module.

15. The audio system defined in claim 1 further comprising a digital gain amplifier to control signal levels of samples being input into the pre-compensator.

16. The audio system defined in claim 1 further comprising an analog gain amplifier responsive to the pre-compensated output to control signal levels of signals corresponding to the pre-compensated output that are to drive the loudspeaker.

17. The audio system defined in claim 1 further comprising a digital multiplier to scale the output of the exact inverse module.

18. A method comprising:
receiving samples of an input signal;
generating a pre-compensated output in response to the samples of an input signal, parameters of a loudspeaker model, and previously predistorted samples of the input signal; and
producing an audio output with a loudspeaker, corresponding to the loudspeaker model, in response to the pre-compensated output.

19. The method defined in claim 18 further comprising using non-linear compensation to modify the samples of the input signal in a manner opposite to distortion that is to occur from the loudspeaker.

20. The method defined in claim 18 wherein generating a pre-compensated output comprises computing the inverse of the loudspeaker model using the samples of an input signal, parameters of the loudspeaker model, and previously distorted samples of the input signal.

21. The method defined in claim 18 wherein generating a pre-compensated output comprising:
calculating coefficients of a polynomial in response to an input signal, parameters of a model of the loudspeaker, and state information regarding past filter outputs; and
determining roots of a polynomial corresponding to the coefficients.

22. The method defined in claim 21 wherein the inverse is given by a second order polynomial.

23. The method defined in claim 21 further comprising selecting a real root from the roots.

24. The method defined in claim 18 further comprising scaling the pre-compensated output.

25. The method defined in claim 18 further comprising controlling signal levels of samples of the input signal prior to generating the pre-compensated output.

26. The method defined in claim 18 further controlling signal levels of signals corresponding to the pre-compensated output that are to drive the loudspeaker, in response to the pre-compensated output.

27. An article of manufacture having one or more recordable media storing instructions which, when executed by a system, cause the system to perform a method comprising:
receiving samples of an input signal;
generating a pre-compensated output in response to the samples of an input signal, parameters of a loudspeaker model, and previously predistorted samples of the input signal; and
producing an audio output with a loudspeaker, corresponding to the loudspeaker model, in response to the pre-compensated output.

28. The article of manufacture defined in claim 27 wherein generating a pre-compensated output comprising:
calculating coefficients of a polynomial in response to an input signal, parameters of a model of the loudspeaker, and state information regarding past filter outputs; and
determining roots of a polynomial corresponding to the coefficients.
